(19) United States
(12) Patent Application Publication
(10) Pub. No.: US 2024/0414937 A1
(43) Pub. Date: Dec. 12, 2024

(54) Organic Light-Emitting Transistor, Manufacturing Method thereof, Light Emitting Substrate, and Display Apparatus

(71) Applicant: BOE Technology Group Co., Ltd., Beijing (CN)

(72) Inventors: Peng WANG, Beijing (CN); Juan ZHANG, Beijing (CN); Xiaohu LI, Beijing (CN); Qingyu HUANG, Beijing (CN); Zhiqiang JIAO, Beijing (CN)

(21) Appl. No.: 18/700,731

(22) PCT Filed: May 11, 2023
(86) PCT No.: PCT/CN2023/093450

§ 371 Date: Apr. 12, 2024

(30) Foreign Application Priority Data
May 30, 2022 (CN) 202210605278.6

(51) Int. Cl. H10K 50/30; H10K 50/805; H10K 71/00; H10K 71/60

(52) U.S. Cl. CPC H10K 50/30; H10K 50/805; H10K 71/60; H10K 71/621

(57) ABSTRACT

An organic light-emitting transistor (200), comprising: a gate (214) arranged on a substrate (202), a gate insulation layer (206), a source (204), a light-emitting functional layer (218), and a drain (220). The side surface of the source (204) facing the light-emitting functional layer (218) is in contact with the light-emitting functional layer (218).

The present application is a U.S. National Phase Entry of International Application No. PCT/CN2023/093450 having an international filing date of May 11, 2023, which claims priority to Chinese Patent Application No. 202210605278.6, filed to the CNIPA on May 30, 2022, contents of the above-identified applications should be understood as being incorporated into the present disclosure by reference.

### TECHNICAL FIELD

Embodiments of the present disclosure relate to, but are not limited to, the field of display technologies, in particular to an organic light emitting transistor and a manufacturing method thereof, a light emitting substrate, and a display apparatus.

### BACKGROUND

An Organic Light Emitting Transistor (OLET) is a device that integrates a switching function of an Organic Field-Effect Transistor (OFET) and an electroluminescence function of an organic electroluminescent device (OLED). An OLET device is simple in structure, mature in preparation process, light and thin, and easy to miniaturize, and has become one of development trends of display technologies in the future.

### SUMMARY

The following is a summary of subject matters described herein in detail. The summary is not intended to limit the protection scope of claims.

The embodiments of the present disclosure provide an organic light emitting transistor and a manufacturing method thereof, a light emitting substrate, and a display apparatus.

A first aspect of an embodiment of the present disclosure provides an organic light emitting transistor including: a gate, a gate insulation layer, a source electrode, a light emitting functional layer, and a drain electrode which are disposed on a substrate; wherein a side surface of the source electrode towards the light emitting functional layer is in contact with the light emitting functional layer.

A second aspect of an embodiment of the present disclosure provides a light emitting substrate including a plurality of organic light emitting transistors according to the first aspect arranged in an array.

A third aspect of an embodiment of the present disclosure provides a display apparatus including the light emitting substrate according to the second aspect.

A fourth aspect of an embodiment of the present disclosure provides a manufacturing method of an organic light emitting transistor, including: forming a source electrode, a gate insulation layer, a gate, a light emitting functional layer, and a drain electrode on a substrate; wherein a side surface of the source electrode towards the light emitting functional layer is in contact with the light emitting functional layer.

Other aspects may be comprehended after drawings and detailed description are read and understood.

### BRIEF DESCRIPTION OF DRAWINGS

In order to describe technical solutions of the embodiments of the present disclosure more clearly, the drawings to be used in the embodiments of the present disclosure will be introduced below in brief. The drawings described below are only some of the embodiments of the present disclosure, and those of ordinary skill in the art may obtain other drawings according to these drawings without paying any inventive effort.

FIG. 1A shows a schematic diagram of an organic light emitting transistor.

FIG. 1B shows a schematic diagram of another organic light emitting transistor.

FIG. 2A shows a schematic diagram of an exemplary organic light emitting transistor according to an embodiment of the present disclosure.

FIG. 2B shows a schematic diagram of another exemplary organic light emitting transistor according to an embodiment of the present disclosure.

FIG. 3 shows a schematic flowchart of an exemplary manufacturing method according to an embodiment of the present disclosure.

FIG. 4A shows a schematic diagram of an exemplary semi-finished product of an organic light emitting transistor according to an embodiment of the present disclosure.

FIG. 4B shows a schematic diagram of another exemplary semi-finished product of an organic light emitting transistor according to an embodiment of the present disclosure.

FIG. 4C shows a schematic diagram of another exemplary semi-finished product of an organic light emitting transistor according to an embodiment of the present disclosure.

FIG. 4D shows a schematic diagram of another exemplary semi-finished product of an organic light emitting transistor according to an embodiment of the present disclosure.

FIG. 4E shows a schematic diagram of another exemplary semi-finished product of an organic light emitting transistor according to an embodiment of the present disclosure.

FIG. 4F shows a schematic diagram of another exemplary semi-finished product of an organic light emitting transistor according to an embodiment of the present disclosure.

FIG. 4G shows a schematic diagram of another exemplary semi-finished product of an organic light emitting transistor according to an embodiment of the present disclosure.

FIG. 4H shows a schematic diagram of another exemplary semi-finished product of an organic light emitting transistor according to an embodiment of the present disclosure.

FIG. 4I shows a schematic diagram of another exemplary semi-finished product of an organic light emitting transistor according to an embodiment of the present disclosure.

FIG. 4J shows a schematic diagram of an exemplary top view structure of an organic light emitting transistor according to an embodiment of the present disclosure.

FIG. 4K shows a schematic diagram of another exemplary top view structure of an organic light emitting transistor according to an embodiment of the present disclosure.

FIG. 5A shows a schematic diagram of another exemplary semi-finished product of an organic light emitting transistor according to an embodiment of the present disclosure.

FIG. 5B shows a schematic diagram of another exemplary semi-finished product of an organic light emitting transistor according to an embodiment of the present disclosure.

FIG. 5C shows a schematic diagram of another exemplary semi-finished product of an organic light emitting transistor according to an embodiment of the present disclosure.

FIG. 5D shows a schematic diagram of another exemplary semi-finished product of an organic light emitting transistor according to an embodiment of the present disclosure.

### DETAILED DESCRIPTION

The embodiments of the present disclosure will be described below in combination with the drawings in detail.

It should be noted that, unless otherwise defined, technical terms or scientific terms used in the embodiments of the present disclosure shall have general meanings understood by those skilled in the art to which the embodiments of the present disclosure pertains. “First”, “second”, and a similar term used in the embodiments of the present disclosure do not represent any order, quantity, or importance, but are only used for distinguishing different components. “Include”, “contain”, or a similar word means that an element or object appearing before the word covers an element or object listed after the word and its equivalent, but does not exclude another element or object. “Connect”, “couple”, or a similar word is not limited to a physical or mechanical connection, but may include an electrical connection, whether direct or indirect. “Upper”, “lower”, “left”, and “right”, etc., are only used for representing relative positional relationships, and when an absolute position of a described object is changed, a relative positional relationship may also be correspondingly changed.

A horizontal structure of an ordinary transistor is adopted for some organic light emitting transistors, which leads to a narrow conductive channel, affects a light emitting area adversely, and has a relatively low luminous efficiency.

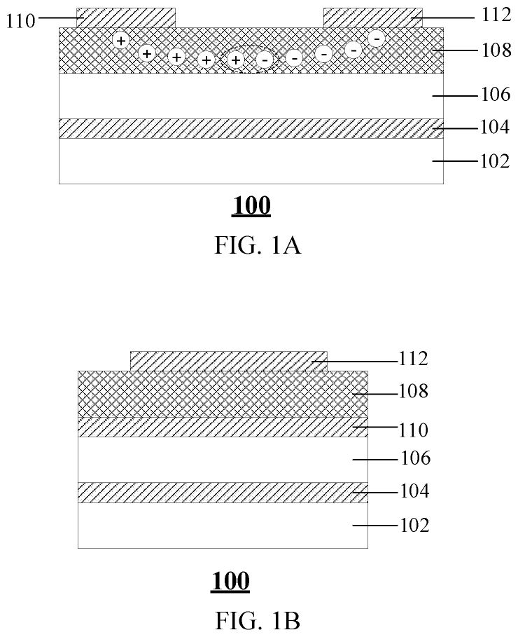

FIG. 1A shows a schematic diagram of an organic light emitting transistor 100.

As shown in FIG. 1A, the organic light emitting transistor 100 may include a gate 104 disposed on a substrate 102, a Gate Insulation layer (GI) 106 disposed on the gate 104, an active layer 108 disposed on the gate insulation layer 106, and a source electrode 110 and a drain electrode 112 disposed on the active layer 108.

A working principle of the organic light emitting transistor 100 is that a voltage of the gate 104 not only controls a source and drain current of a transistor portion, but also controls an area and a light emitting intensity of a light emitting region. As may be seen from FIG. 1A, such a transistor structure in which the source electrode 110 and the drain electrode 112 are horizontally arranged enables electrons and holes to be able to recombine only in a region between the source electrode and the drain electrode to excite a material to emit light, and since a carrier mobility of an organic evaporation material is relatively low, it is easy to cause problems of a high working voltage, a low efficiency, a short life, and a small aperture ratio of a device.

FIG. 1B shows a schematic diagram of another organic light emitting transistor.

As shown in FIG. 1B, the organic light emitting transistor 100 may include a gate 104 disposed on a substrate 102, a Gate Insulation layer (GI) 106 disposed on the gate 104, a source electrode 110 disposed on the gate insulation layer 106, an active layer 108 disposed on the source electrode 110, and a drain electrode 112 disposed on the active layer 108.

Thus, the organic light emitting transistor 100 may have a vertical channel, thereby forming a Vertical Organic Field-Effect Transistor (VOFET). VOFET can provide a higher channel current than a horizontal Organic Thin-Film Transistor (OTFT) due to a conductive channel of vertical transmission.

A Vertical-type Organic Light Emitting Transistor (VOLET) based on a Vertical Organic Field-Effect Transistor (VOFET) structure can achieve an OLET of area light emitting and improve an aperture ratio, and is a promising display technology. However, for a display application requiring a high resolution, it is difficult to finely process an organic semiconductor material by lithography, and the VOLET structure needs to construct a source electrode and a drain electrode on the organic semiconductor material, which leads to a relatively low resolution and yield of VOLET devices. Moreover, the structure may be directly formed as an OLED structure since the source electrode and drain electrode are completely overlapped, which makes it more difficult for a gate to control a channel current and affects brightness adjustment of an OLET adversely. In some solutions, in order to provide a control effect of a gate in such a structure, the gate 104 may be made of a material having a special structure, and a manufacturing process of such a material is complicated, which will increase a process difficulty.

In view of this, an embodiment of the present disclosure provides an organic light emitting transistor, which may be manufactured using a process that is easy to implement and has a relatively high aperture ratio and light efficiency.

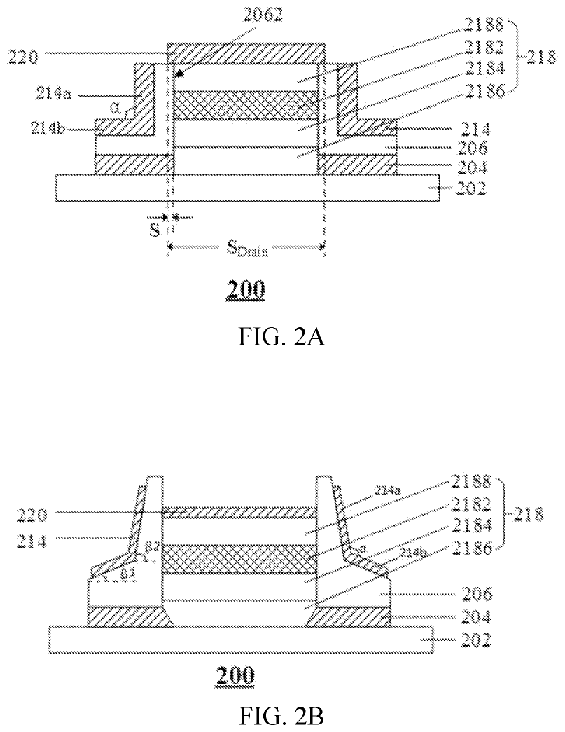

FIG. 2A shows a schematic diagram of an organic light emitting transistor 200 according to an embodiment of the present disclosure.

As shown in FIG. 2A, the organic light emitting transistor 200 may include a gate 214, a gate insulation layer 206, a source electrode 204, a light emitting functional layer 218, and a drain electrode 220 which are disposed on a substrate 202. Herein, as shown in FIG. 2A, with respect to the source electrode 204, the drain electrode 220 is disposed on a side of the light emitting functional layer 218 away from the substrate 202, so that a vertical channel may be formed between the source electrode 204 and the drain electrode 220, thereby improving a light efficiency. As an optional embodiment, the light emitting functional layer 218 may further include a first charge injection layer 2186 (e.g., an Electron Injection Layer (EIL)), a first charge transport layer 2184 (e.g., an Electron Transport Layer (ETL)), an Emitting Layer (EL) 2182, and a second charge transport layer 2188 (e.g., a Hole Transport Layer (HTL)). It may be understood that the light emitting functional layer 218 may further include another hierarchical structure, such as a second charge injection layer disposed on a side of the second charge transport layer 2188 away from the emitting layer 2182, and a charge block layer disposed on at least one side of the emitting layer 2182, etc.

As an optional embodiment, a side surface of the source electrode 204 towards the light emitting functional layer 218 is in contact with the light emitting functional layer 218. In this way, the source electrode 204 is not completely overlapped with the light emitting functional layer 218, but is in contact with a hierarchical structure of the light emitting functional layer 218 from the side surface (a surface perpendicular to the substrate 202) (for example, in contact with the first charge injection layer 2186). When the drain electrode 220 is disposed on the light emitting functional layer 218 (a direction away from the substrate 202), a projection of the drain electrode 220 is not completely overlapped with a projection of the source electrode 204, and it is difficult to form a diode structure, so that a control effect of the gate 214 is better. In addition, when manufacturing the organic light emitting transistor 200, each film layer in a hierarchical structure may be manufactured using a conventional material without using a complex process, thereby reducing a process difficulty.

In some embodiments, as shown in FIG. 2A, in order to ensure a gate control effect, an overlapping area S between an orthographic projection of the drain electrode 220 on the substrate 202 and an orthographic projection of the source electrode 204 on the substrate 202 is less than or equal to a product of an area Sprain of the drain electrode and a preset ratio k (since FIG. 2A is a cross-sectional view, the area is indicated by a straight line), that is, S≤k·S_{Drain}. As an optional embodiment, the preset ratio k may be 10%, thereby ensuring the gate control effect on one hand and better forming a conductive channel in the light emitting functional layer 218 on the other hand.

In some embodiments, as shown in FIG. 2B, a surface of the source electrode 204 towards the light emitting functional layer 218 may have a slope, so that a contact area of the source electrode 204 with the first charge injection layer 2186 may be increased to some extent, charge injection may be increased, and an influence on the gate control effect may be reduced. In some embodiments, in order to increase charge injection, it may also be achieved by increasing a thickness of the source electrode 204.

In some embodiments, as shown in FIG. 2A, a gate insulation layer 206 is disposed between the source electrode 204 and the gate 214, and the gate insulation layer 206 includes a side surface 2062 perpendicular to the substrate 202, which is disposed around a periphery of the light emitting functional layer 218. Thus, the gate insulation layer 206 may be formed before the light emitting functional layer 218 is manufactured, and then the gate insulation layer 206 is used as a Pixel Definition Layer (PDL), so that the emitting layer 2182 of the light emitting functional layer 218 may be manufactured by means of printing, and a process difficulty can be reduced compared with an evaporation process. It may be understood that the perpendicular here may not be completely perpendicular (i.e., 90 degrees) but basically perpendicular. According to characteristics of a manufacturing process, it is possible to form an inclined surface to a certain extent when a perpendicular side surface is formed, so when an angle formed between the side surface 2062 and the substrate 202 is between 80 and 100 degrees, it may be considered to be perpendicular.

Accordingly, as shown in FIG. 2A, taking a surface perpendicular to the substrate 202 as a cross-section, a cross-sectional shape of the gate insulation layer 206 may be L-shaped, so that with respect to the source 202, the gate 214 is disposed on a side of the gate insulation layer 206 away from the light emitting functional layer 218, and then a cross-sectional shape of the gate 214 may include a first portion 214a and a second portion 214b which are connected with each other, wherein the first portion 214a extends towards a first direction, the second portion 214b extends towards a second direction, and an angle α between the first portion 214a and the second portion 214b is approximately equal to 90 degrees (e.g., 80 degrees to 100 degrees). In this way, the gate 214 may cover an outer peripheral surface of the light emitting functional layer 218, so that a control effect of the gate 214 may be improved. Accordingly, it may be understood that a shape of a projection of the gate 214 on the substrate 202 may be annular (including, but not limited to, a circular ring, a square ring, or a polygonal ring etc.), so that a complete covering effect may be formed.

In some embodiments, as shown in FIG. 2B, a thickness (a length in a direction perpendicular to the substrate 202) of the gate insulation layer 206 is gradually reduced along a direction away from the light emitting functional layer 218, and thus a slope may be formed on a side of the gate insulation layer 206 away from the light emitting functional layer 218, so that when the gate 214 is formed on the gate insulation layer 206 subsequently, it is not necessary to climb on a vertical surface, but may be formed on a surface having a slope, and the gate 214 can be better formed. As shown in FIG. 2B, a side of the gate insulation layer 206 away from the source electrode 204 and away from the light emitting functional layer 218 forms a side slope (or referred to as a slope). In the example, the side slope in a direction perpendicular to the substrate is in a shape of a polygonal line, and in other examples, the side slope may be in a shape of an arc line. As an optional embodiment, as shown in FIG. 2B, the gate insulation layer 206 may have two slopes, including a first slope β1 away from the light emitting functional layer 218 and a second slope β2 close to the light emitting functional layer 218, wherein the first slope β1 is more gentle than the second slope β2. For example, the first slope β1 may be less than 45°, and the second slope β2 may be greater than 45°. In this way, when the gate 214 is formed on the gate insulation layer 206, as shown in FIG. 2B, taking a surface perpendicular to the substrate 202 as a cross section, a cross-sectional shape of the gate 214 may include a first portion 214a and a second portion 214b, and an included angle α between the first portion 214a and the second portion 214b may be greater than 90 degrees and less than 180 degrees, thereby forming a better covering effect.

In some embodiments, a shape of an orthographic projection of the source electrode 204 on the substrate 202 is annular, so that a conductive channel may be better formed between the source electrode 204 and the drain electrode 220.

In some embodiments, in order to further improve the gate control effect, two gates may be disposed, and the two gates 214 may be formed on both sides of the light emitting functional layer 218, thereby forming a double-gate structure. As an optional embodiment, there may be two source electrodes 204, which may be respectively disposed on both sides of the light emitting functional layer 218. The gate insulation layer 206 may also be disposed as two portions, which are respectively disposed on both sides of the light emitting functional layer 218.

In some embodiments, as shown in FIG. 2B, an end face of the gate insulation layer 206 away from the substrate 202 may be higher than a surface of the drain electrode 220 away from the substrate 202, and the drain electrode 220 and the gate 214 have a same thickness and manufacturing material, so that the gate 214 and the drain electrode 220 may be manufactured in a one-time patterning process, thereby reducing process acts and improving a production efficiency.

The organic light emitting transistor according to the embodiment of the present disclosure achieves a technical solution that the OLET is optimized from linear light emitting to area light emitting through a device structure design of a vertical channel, which solves problems of a low aperture ratio, a high working voltage, a low light emitting efficiency, and a short service life of a horizontal channel OLET device, achieves an effect of enlarging a light emitting region, and improves an aperture ratio.

A novel vertical channel OLET device design according to an embodiment of the present disclosure may easily achieve a double-gate structure in a process, enhance a gate control capability of a device, and achieve effects of increasing a conduction current of the device and improving a current switching ratio. Moreover, in some embodiments, due to an L-shaped structure of a gate, an electric field intensity at a folding angle is relatively large, which can increase an electric field of a source electrode perpendicular to a surface of the gate, be beneficial to increasing longitudinal propagation of charges in a corresponding channel region, and achieve an effect of increasing a vertical current.

In addition, in some embodiments, a device structure of the vertical channel, the gate, and the gate insulation layer may replace a role of a Pixel Definition Layer (PDL), and an additional PDL is not needed, which may save a mask cost and reduce process complexity.

Further, an embodiment of the present disclosure also provides a manufacturing method of an organic light emitting transistor, and the manufacturing method may include forming a source electrode, a gate insulation layer, a gate, a light emitting functional layer, and a drain electrode on a substrate; wherein a side surface of the source electrode towards the light emitting functional layer is in contact with the light emitting functional layer. The organic light emitting transistor may have a vertical channel, may be manufactured by using an easy-to-implement process, and may have a relatively high aperture ratio and light efficiency.

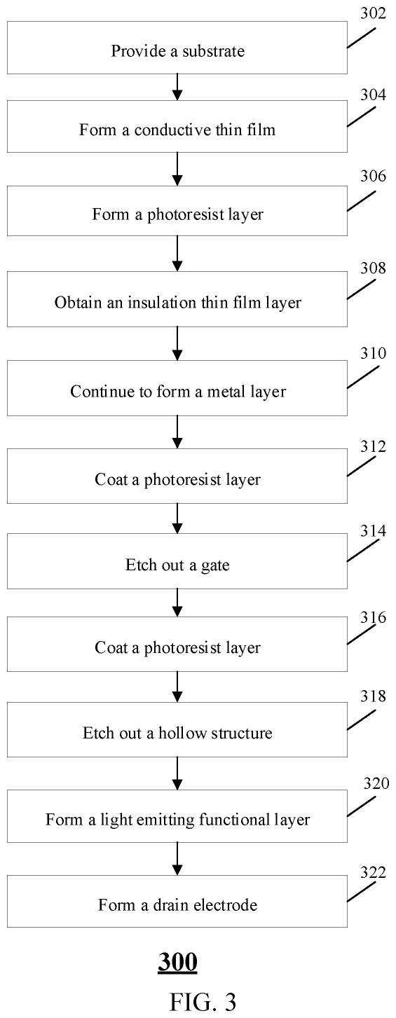

FIG. 3 shows a schematic flowchart of an exemplary manufacturing method 300 according to an embodiment of the present disclosure. As shown in FIG. 3, the manufacturing method 300 may further include the following acts.

In act 302, a substrate 202 may be provided.

Optionally, a synthetic resin such as glass, PolyEthylene glycol Terephthalate (PET), PolyEther Sulphone (PES), PolyCarbonate (PC), or a silicon wafer may be used for the substrate 202. When preparing a single-side area light emitting device, a silicon wafer may be used; and a gate may be formed by depositing glass of Indium Tin Oxide (ITO) when preparing a double-side area light emitting device.

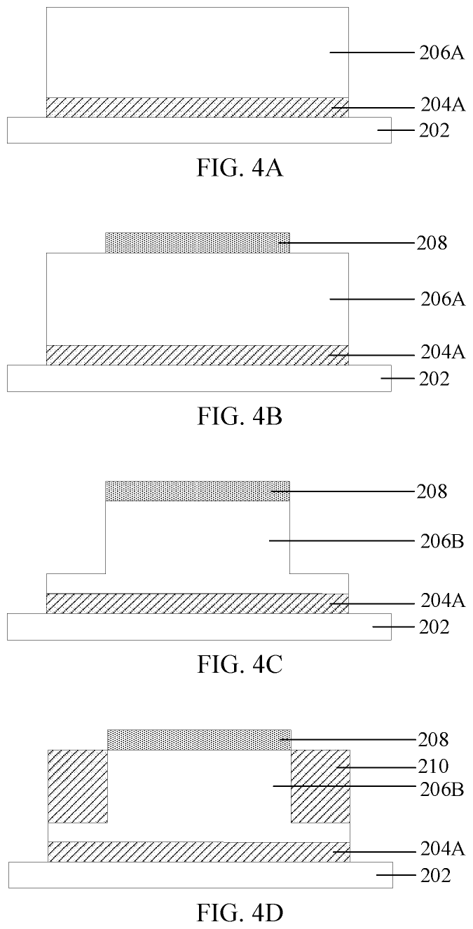

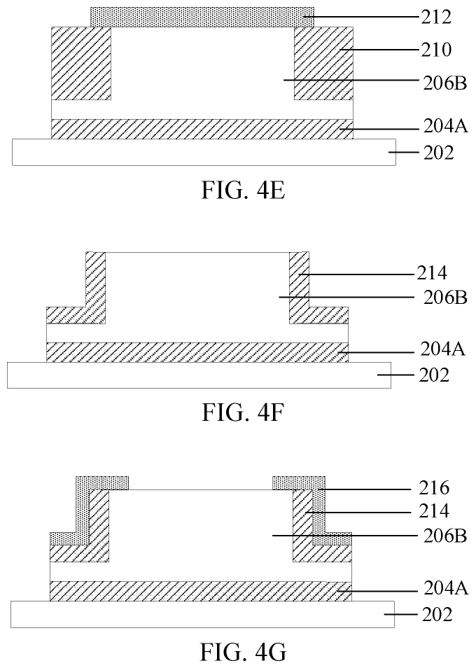

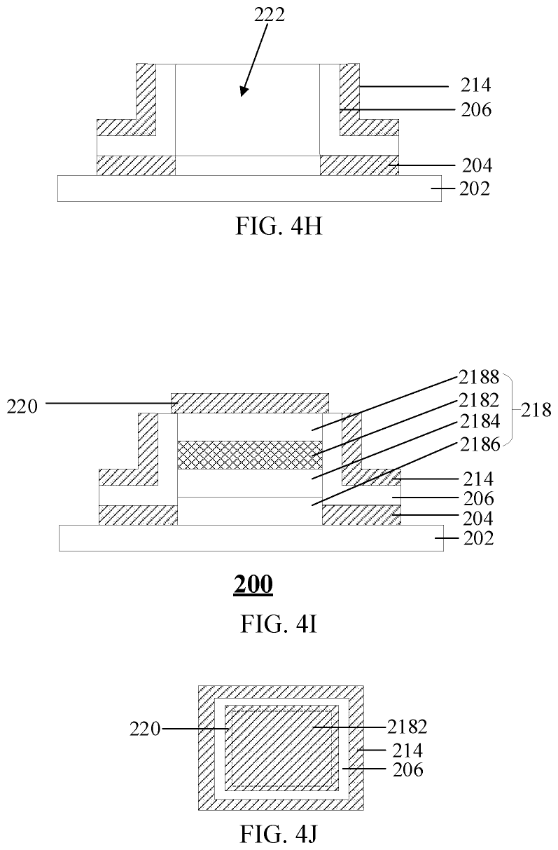

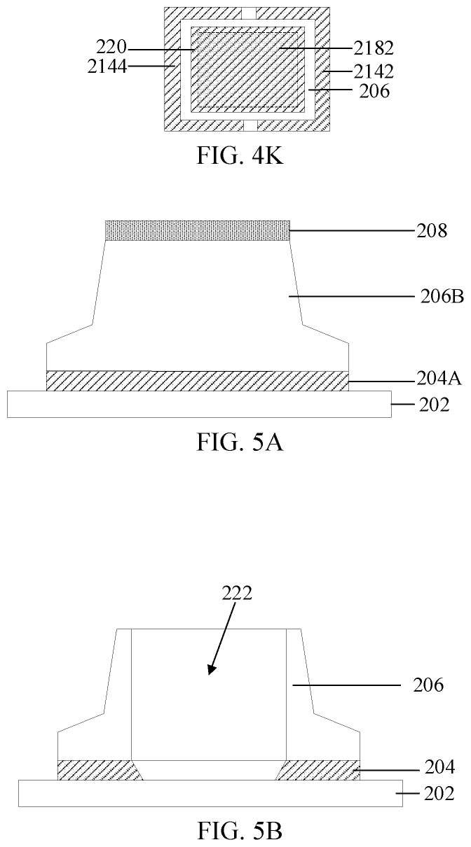

In act 304, a conductive thin film (e.g., metal or ITO) 204A used for manufacturing a source electrode 204 may be formed on the substrate 202, and an insulation thin film 206A used for manufacturing a gate insulation layer 206 may be further formed, as shown in FIG. 4A.

Optionally, a material of the conductive thin film 204A may be selected from metals such as gold, silver, copper, aluminum, and magnesium, or a combination of metals. Considering a work function, conductivity, and light transmittance of a metal electrode, a source electrode may be made of gold and may be prepared by means of evaporation, with a thickness of about 80 Å.

Optionally, a material of the insulation thin film 206A may be selected from an insulation layer material used for the organic light emitting transistor, such as Aluminum Oxide (Al₂O₃), Silicon Nitride (SiNx), and Silicon Oxide (SiO₂). Considering parameters such as a dielectric constant of a dielectric material, the insulation thin film 206A as a dielectric layer may be made of Aluminum Oxide (Al₂O₃) and may be prepared by means of Atomic Layer Deposition (ALD), with a thickness of about 200 nm.

In act 306, a photoresist layer 208 may be formed on the insulation thin film 206A, as shown in FIG. 4B.

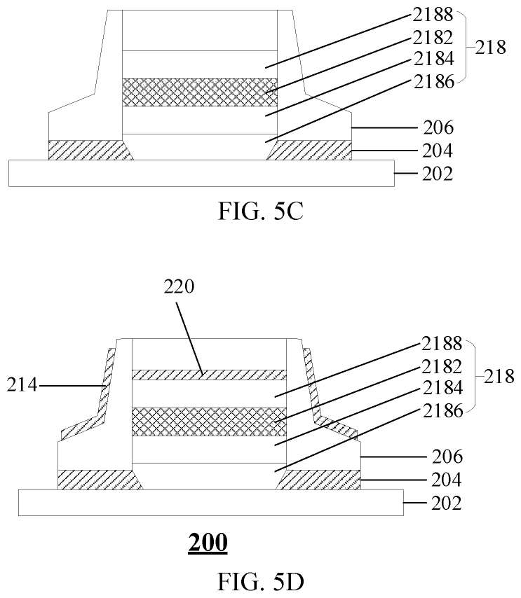

In act 308, the insulation thin film 206A may be etched to further form a region (with a thickness of about 200 nm) used for forming a gate 214 on the insulation thin film 206A, and an insulation thin film layer 206B is obtained, as shown in FIG. 4C. As an optional embodiment, when the insulation thin film layer 206B is formed in act 308, instead of forming a completely vertical structure, a structure with a slope may be formed to facilitate formation of a gate. Optionally, as shown in FIG. 5A, the insulation thin film layer 206B may have a first slope and a second slope, so that a subsequently formed gate has a corner with not completely 90 degrees, which facilitates smooth electric field transition.

In act 310, a metal layer 210 is continuously formed in a region where the insulation thin film layer 206B is etched, as shown in FIG. 4D. Optionally, a material of the metal layer 210 may be selected from metals such as gold, silver, copper, aluminum, and magnesium, or a combination of metals.

In act 312, a photoresist layer 212 may be further coated, as shown in FIG. 4E, the photoresist layer 212 may protect an evaporation region (central region) and a gate region of an Emitting Layer (EL).

In act 314, an L-shaped gate 214 may be etched out, as shown in FIG. 4F. In some embodiments, the gate 214 may not have completely 90 degrees and may have a slope at a corner, which may make Gate field transition at a vertical channel smoother. In this act, if a double-gate structure is to be formed, the gate 214 may be disconnected from a middle portion during etching (referring to FIG. 4K).

In act 316, a photoresist layer 216 may be further coated, as shown in FIG. 4G, and the photoresist layer 216 may protect a gate insulator region that needs to be retained.

In act 318, a hollow structure 222 may be etched out in the insulation thin film layer 206B and the conductive thin film 204A, as shown in FIG. 4H.

In act 320, a light emitting functional layer 218 may be formed in the hollow structure 222, as shown in FIG. 4I.

Optionally, a first charge injection layer 2186 (e.g., an Electron Injection Layer (EIL)), a first charge transport layer 2184 (e.g., an Electron Transport Layer (ETL)), an Emitting Layer (EL) 2182, and a second charge transport layer 2188 (e.g., a Hole Transport Layer (HTL)) may be sequentially deposited in the hollow structure 222 to obtain a vertical channel OLET as shown in FIG. 4I. For convenience of understanding, FIGS. 4J and 4K respectively give schematic diagrams of two top view structures of the organic light emitting transistor 200, wherein a dashed line box shows a boundary of the emitting layer 2182. Herein, FIG. 4J shows an embodiment in which a projection of the gate 214 is annular, and FIG. 4K shows an embodiment of a double-gate structure, in which gates 2142 and 2144 are included.

Optionally, materials of the above-described plurality of functional layers of the light emitting functional layer 218 and the emitting layer may be selected from materials used for organic light emitting diodes, for example, an organic transport material with a high mobility and an emitting layer material with a high light emitting efficiency may be selected. All of the above-described organic semiconductor materials may be prepared by means of vacuum evaporation. In particular, due to a special pixel well structure of this embodiment, the hollow structure 222 formed by the gate 214 and the gate insulation layer 206 may achieve a PDL effect, therefore the emitting layer 2182 may also be prepared by using a printing process. It may be understood that selection of the above-described plurality of film layer materials and thickness adjustment may have an impact on device performance and a light emitting color, and parameters may be set according to actual needs, which will not be repeated here.

In act 322, a drain electrode 220 may be formed on the light emitting functional layer 218, as shown in FIG. 4I. Optionally, a material of the drain electrode 220 may be selected from metals such as gold, silver, copper, aluminum, and magnesium, or a combination of metals. Considering a work function, conductivity, and light transmittance of a metal electrode, a source electrode may be made of gold and may be prepared by means of evaporation, with a thickness of about 80 Å.

So far, manufacturing of the organic light emitting transistor 200 has been completed.

The manufacturing method of the organic light emitting transistor according to the embodiment of the present disclosure may obtain an organic light emitting transistor with a novel vertical channel, which may solve a problem of linear light emitting of an OLET device and achieve area light emitting. Moreover, due to a vertical channel design, it is easier to achieve a double-gate structure in a process, enhance a gate control capability of a device, and achieve effects of increasing a conduction current of the device and improving a current switching ratio. In addition, based on a device structure with a vertical channel, the gate and the GI layer may replace a role of a pixel definition layer PDL, which saves a mask cost and reduces process complexity.

In some embodiments, the gate 214 and drain electrode 220 may be formed through a one-time patterning process, which may save process and mask, improve a utilization rate of a material and process efficiency, and reduce a cost.

As shown in FIG. 5A, an insulation thin film layer 206B having a slope may be formed in order to avoid that a subsequent gate cannot be attached to the insulation thin film layer 206B.

After the insulation thin film layer 206B is formed, the hollow structure 222 may be etched out directly in the insulation thin film layer 206B and the conductive thin film 204A, as shown in FIG. 5B.

Then, a light emitting functional layer 218 may be further formed in the hollow structure 222, as shown in FIG. 5C.

Next, through forming and patterning the conductive thin film, the gate 214 and the drain electrode 220 may be obtained simultaneously, as shown in FIG. 5D.

In this embodiment, when the gate 214 and the drain electrode 220 are formed through a one-time patterning process, a height of the gate insulation layer 206 may be higher than a total thickness of the light emitting functional layer 218 and the drain electrode 220 (i.e., an end face of the gate insulation layer 206 away from the substrate 202 may be higher than a surface of the drain electrode 220 away from the substrate 202), so as to ensure that the gate 214 and the drain electrode 220 may be completely disconnected, and the gate 214 may form a continuous conductive channel in a corresponding region of the light emitting functional layer 218 to ensure a device to work normally.

A structure of the gate 214 formed in this embodiment may increase a contact area between an electrode and an organic layer and achieve more efficient electron injection.

An embodiment of the present disclosure also provides a light emitting substrate, and any embodiment or an arrangement and combination of embodiments of a plurality of the aforementioned organic light emitting transistors 200 arranged in an array, which may have technical effects of corresponding embodiment, which will not be repeated here.

In some embodiments, the light emitting substrate may be a display substrate and may display a color image.

In other embodiments, the light emitting substrate may be a backlight source in a backlight module and may be applied in a liquid crystal display panel for providing a backlight.

An embodiment of the present disclosure also provides a display apparatus, which may include the aforementioned light emitting substrate embodiment, and may have corresponding technical effects, which will not be repeated here.

In some embodiments, the display apparatus may further include a drive circuit coupled with the light emitting substrate, and the drive circuit is configured to provide an electrical signal to the light emitting substrate.

It may be understood that the display apparatus is a product with an image display function, which may be, for example, a display, a television, a billboard, a digital photo frame, a laser printer with a display function, a telephone, a mobile phone, a Personal Digital Assistant (PDA), a digital camera, a portable camcorder, a viewfinder, a navigator, a vehicle, a large area wall, a household appliance, and an information inquiry device (such as a business inquiry device of e-government, a bank, a hospital, and an electric power department, and a monitor).

Those skilled in the art should understand that discussion of any of the above embodiments is only exemplary and is not intended to imply that the scope of the embodiments of the present disclosure (including the claims) is limited to these examples; under a concept of the embodiments of the present disclosure, the above embodiments or technical features in different embodiments may be combined, and acts may be implemented in any order. There are many other changes in different aspects of the embodiments of the present disclosure as described above, which are not provided in detail for the sake of brevity.

In addition, well-known power/ground connections with an Integrated Circuit (IC) chip and another component may or may not be shown in the drawings provided in order to simplify description and discussion and not to obscure the embodiments of the present disclosure. Moreover, an apparatus may be illustrated in a form of a block diagram in order to avoid obscuring the embodiments of the present disclosure, which also considers a following fact, that is, details about implementation modes of apparatuses in these block diagrams highly depend on a platform on which the embodiments of the present disclosure will be implemented (that is, these details should be fully within a understanding range of those skilled in the art). With the details (for example, circuits) elaborated to describe exemplary embodiments of the embodiments of the present disclosure, it is apparent to those skilled in the art that the embodiments of the present disclosure may be implemented without these details or in a case that these details are changed. Therefore, these descriptions should be considered as illustrative rather than restrictive.

Although description has been made in combination with some embodiments of the present disclosure, many alternatives, modifications, and variations of these embodiments will be obvious to those skilled in the art according to the foregoing description. The embodiments of the present disclosure are intended to cover all such alternatives, modifications, and variations that fall within the broad scope of the appended claims. Therefore, any omissions, modifications, equivalent replacements, improvements, etc., made within the spirit and principle of the embodiments of the present disclosure shall be included within the protection scope of the embodiments of the present disclosure.

1. An organic light emitting transistor, comprising:
a gate, a gate insulation layer, a source electrode, a light emitting functional layer, and a drain electrode which are disposed on a substrate;
wherein a side surface of the source electrode towards the light emitting functional layer is in contact with the light emitting functional layer.

2. The organic light emitting transistor according to claim 1, wherein with respect to the source electrode, the drain electrode is disposed on a side of the light emitting functional layer away from the substrate; and an overlapping area S between an orthographic projection of the drain electrode on the substrate and an orthographic projection of the source electrode on the substrate is less than or equal to a product of an area S_{Drain} of the drain electrode and a preset ratio k.

3. The organic light emitting transistor according to claim 1, wherein a surface of the source electrode towards the light emitting functional layer has a slope.

4. The organic light emitting transistor according to claim 1, wherein the gate insulation layer is disposed between the source electrode and the gate, the gate insulation layer comprises a side surface perpendicular to the substrate, and the side surface is disposed around a periphery of the light emitting functional layer.

5. The organic light emitting transistor according to claim 4, wherein a thickness of the gate insulation layer gradually decreases along a direction away from the light emitting functional layer.

6. The organic light emitting transistor according to claim 4, wherein with respect to the source electrode, the gate is disposed on a side of the gate insulation layer away from the light emitting functional layer.

7. The organic light emitting transistor according to claim 6, wherein taking a surface perpendicular to the substrate as a cross section, a cross-sectional shape of the gate comprises a first portion and a second portion, and an included angle between the first portion and the second portion is greater than or equal to 90 degrees.

8. The organic light emitting transistor according to claim 7, wherein an orthographic projection of the source electrode on the substrate is annular, and/or an orthographic projection of the gate on the substrate is annular.

9. The organic light emitting transistor according to claim 7, wherein the organic light emitting transistor comprises two gate, and the two gates are disposed on both sides of the light emitting functional layer.

10. The organic light emitting transistor according to claim 4, wherein an end face of the gate insulation layer away from the substrate is higher than a surface of the drain electrode away from the substrate, and the drain electrode and the gate have a same thickness and manufacturing material.

11. A light emitting substrate, comprising a plurality of organic light emitting transistors according to claim 1 arranged in an array.

12. A display apparatus, comprising a light emitting substrate according to claim 11.

13. A manufacturing method of an organic light emitting transistor, comprising:
forming a source electrode, a gate insulation layer, a gate, a light emitting functional layer, and a drain electrode on a substrate;
wherein a side surface of the source electrode towards the light emitting functional layer is in contact with the light emitting functional layer.

14. The manufacturing method according to claim 13, wherein the forming the source, the gate insulation layer, the gate, the light emitting functional layer, and the drain electrode on the substrate comprises:
forming the source electrode and the gate insulation layer on the substrate, wherein the source electrode and the gate insulation layer form a hollow structure; and
forming the light emitting functional layer in the hollow structure.

15. The manufacturing method according to claim 14, wherein the forming the source, the gate insulation layer, the gate, the light emitting functional layer, and the drain electrode on the substrate comprises:
forming the gate and the drain electrode through a one-time patterning process.

16. The organic light emitting transistor according to claim 2, wherein a surface of the source electrode towards the light emitting functional layer has a slope.

17. The organic light emitting transistor according to claim 5, wherein with respect to the source electrode, the gate is disposed on a side of the gate insulation layer away from the light emitting functional layer.

18. A light emitting substrate, comprising a plurality of organic light emitting transistors according to claim 2 arranged in an array.

19. A light emitting substrate, comprising a plurality of organic light emitting transistors according to claim 3 arranged in an array.

20. A light emitting substrate, comprising a plurality of organic light emitting transistors according to claim 4 arranged in an array.
